(19) United States
(12) Patent Application Publication
(10) Pub. No.: US 2013/0137217 A1
(43) Pub. Date: May 30, 2013

(54) METHOD OF MANUFACTURING SEMICONDUCTOR DEVICE

(71) Applicant: Elpida Memory, Inc., Tokyo (JP)

(72) Inventors: Osamu KINDO, Tokyo (JP); Sensho Usami, Tokyo (JP); Koji Hosokawa, Tokyo (JP)

(73) Assignee: Elpida Memory, Inc., Tokyo (JP)

(21) Appl. No.: 13/685,078

(22) Filed: Nov. 26, 2012

(30) Foreign Application Priority Data
Nov. 28, 2011 (JP) 2011-259205

(51) Int. Cl. H01L 21/50

(52) U.S. Cl. CPC H01L 21/50
USPC 438/109

(57) ABSTRACT

A method of manufacturing a semiconductor device, comprising preparing a wiring substrate and mounting a first rectangular semiconductor chip having plural of first electrodes arranged along short sides thereof on the wiring substrate. A second rectangular semiconductor chip having plural of second electrodes arranged along short sides thereof is stacked on the first semiconductor chip so that the short sides of the second semiconductor chip are perpendicular to the short sides of the first semiconductor chip and that gaps are formed between the wiring substrate and short side portions of the second semiconductor chip. The method further comprises filling the gaps with a first resin from locations near long sides of the second semiconductor chip in a direction parallel to the short sides of the second semiconductor chip. The first and the second electrodes are connected to connection pads of the wiring substrate by first and second wires, respectively.

This application is based upon and claims priority to prior application Japanese Patent Application No. 2011-259205, filed on Nov. 28, 2011,the disclosure of which is incorporated herein by reference.

### BACKGROUND OF THE INVENTION

1. Field of the Invention

The present invention relates to a method of manufacturing a semiconductor device.

2. Description of Related Art

In order to enhance the density of a semiconductor device, it is common to stack a plurality of semiconductor chips. Such a semiconductor device is called a multi-chip package (MCP) semiconductor device.

In an MCP semiconductor device, part of a semiconductor chip located at an upper stage is usually required to project from a semiconductor chip located at a lower stage for wire bonding. In other words, the semiconductor chip of the upper stage is stacked on the semiconductor chip of the lower stage so that the semiconductor chip of the lower stage has an area which is not covered with the semiconductor chip of the upper stage and the semiconductor chip of the upper stage has an overhang portion for wire bonding. Such an overhang portion may cause generation of chip cracks or warp along with thickness reduction of a semiconductor chip during a subsequent wire bonding process or resin sealing process. Therefore, some reinforcement countermeasures are needed.

Patent Literature 1 discloses the following technology as an example of those reinforcement countermeasures. An adhesive agent is disposed on a wiring substrate. A first semiconductor chip is mounted on the wiring substrate by flip chip bonding, so that the adhesive agent spreads to the exterior of the first semiconductor chip. The excessive adhesive agent supports an overhang portion of a second semiconductor chip mounted on the first semiconductor chip.

Patent Literature 1: JP-A 2000-299431

### SUMMARY

However, if the amount of the spreading adhesive agent is insufficient in the aforementioned semiconductor device, a gap between the upper-stage chip (second semiconductor chip) and the wiring substrate may not filled with the adhesive agent.

Furthermore, in the aforementioned semiconductor device, the first semiconductor chip located at a lower stage is configured so that an adhesive agent spreads from the first semiconductor chip during a flip chip mounting process. Therefore, in a semiconductor device in which three or more semiconductor chips are stacked, it is difficult to support overhang portions of semiconductor chips located at a third stage or higher.

The present invention seeks to provide a method of manufacturing a semiconductor device capable of stably supporting not only an overhang portion of a two-stage multilayer structure, but also overhang portions of a multilayer structure having three or more stages.

In one embodiment, there is provided a method of manufacturing a semiconductor device. The method comprises preparing a wiring substrate having a plurality of connection pads and mounting a first rectangular semiconductor chip having a plurality of first electrodes arranged along short sides thereof on the wiring substrate. The method further comprises stacking a second rectangular semiconductor chip having a plurality of second electrodes arranged along short sides thereof on the first semiconductor chip so that the short sides of the second semiconductor chip are perpendicular to the short sides of the first semiconductor chip and that gaps are formed between the wiring substrate and short side portions of the second semiconductor chip. The method still further comprises filling the gaps with a first resin from locations near long sides of the second semiconductor chip in a direction parallel to the short sides of the second semiconductor chip, electrically connecting the first electrodes and the connection pads to each other by first wires, and electrically connecting the second electrodes and the connection pads to each other by second wires after the filling of the first resin.

In another embodiment, there is provided a method of manufacturing a semiconductor device. The method comprises preparing a wiring substrate including a plurality of connection pads, mounting a first semiconductor chip over the wiring substrate, and stacking a second semiconductor chip over the first semiconductor chip so that at least one side of the second semiconductor chip protrudes from the first semiconductor chip to form a first gap between the wiring substrate and the second semiconductor chip. The second semiconductor chip includes a plurality of first electrodes arranged along the one side thereof. The method further comprises filling the first gap with a first resin, after stacking the second semiconductor chip over the first semiconductor chip.

In still another embodiment, there is provided a method of manufacturing a semiconductor device. The method comprises preparing a wiring substrate including a first surface that is defined by first and second edges opposite to each other and by third and fourth edges opposite to each other. The wiring substrate includes a plurality of first connection pads arranged along each of the first and second edges thereof. The method further comprises preparing first and second semiconductor chips. Each of the first and second semiconductor chips is defined by first and second sides opposite to each other and by third and fourth sides opposite to each other. The first and second sides are longer than the third and fourth sides. Each of the first and second semiconductor chips includes a plurality of first electrodes arranged along each of the third and fourth sides thereof. The method still further comprises mounting the first semiconductor chip over the first surface of the wiring substrate so that the first and second sides of the first semiconductor chip face toward the first and second edges of the wiring substrate and stacking the second semiconductor chip over the first semiconductor chip so that the first and second sides of the second semiconductor chip face toward the third and fourth edges of the wiring substrate. The third and fourth sides of the second semiconductor chip are protruded from the first and second sides of the first semiconductor chip toward the first and second edges of the wiring substrate to form first gaps between the wiring substrate and the second semiconductor chip. The method still further comprises filling the first gaps with a first resin, after stacking the second semiconductor chip over the first semiconductor chip and electrically connecting the first electrodes of the second semiconductor chip to the first connection pads by first wires, after filling the first gaps with the first resin.

According to the present invention, gaps between short side portions of the second semiconductor chip, which is located at a second stage, and a wiring substrate are filled with a first resin so that the overhang portions of the second semiconductor chip are supported by the first resin. Therefore, a thinner semiconductor chip can be used as a semiconductor chip stacked with overhang portions. A sealer used in a subsequent batch molding process can be reduced in thickness, and hence the semiconductor device can be reduced in thickness. Furthermore, reduction in thickness of the sealer results in reduction of warp of the semiconductor device. Since a resin is filled around the overhang portions of the second semiconductor chip, voids are prevented from being generated in the overhang portions. Therefore, the reliability of the semiconductor device can be improved.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view showing a semiconductor device according to a first embodiment of the present invention, excluding part of a sealing resin;

FIG. 2A is a cross-sectional view of the semiconductor device taken along line A-A′ of FIG. 1;

FIG. 2B is a cross-sectional view of the semiconductor device taken along line B-B′ of FIG. 1;

FIG. 3A is a plan view explanatory of a production step of the semiconductor device shown in FIG. 1, in which first and second semiconductor chips are stacked on a wiring mother substrate;

FIG. 3B is a cross-sectional view of FIG. 3A;

FIG. 4A is a plan view explanatory of a production step subsequent to FIG. 3A;

FIG. 4B is a cross-sectional view of FIG. 4A;

FIG. 5A is a plan view explanatory of a production step subsequent to FIG. 4A;

FIG. 5B is a cross-sectional view of FIG. 5A;

FIG. 6A is a plan view explanatory of a production step subsequent to FIG. 5A;

FIG. 6B is a cross-sectional view of FIG. 6A;

FIG. 7A is a plan view explanatory of a production step subsequent to FIG. 6A;

FIG. 7B is a cross-sectional view of FIG. 7A;

FIG. 8A is a plan view explanatory of a production step subsequent to FIG. 7A;

FIG. 8B is a cross-sectional view of FIG. 8A;

FIG. 9A is a cross-sectional view explanatory of a sealing step subsequent to FIG. 8A;

FIG. 9B is a cross-sectional view explanatory of a solder ball mounting step subsequent to FIG. 9A;

FIG. 9C is a cross-sectional view explanatory of a dicing step subsequent to FIG. 9B;

FIG. 10 is a plan view showing a semiconductor device according to a second embodiment of the present invention, excluding part of a sealing resin;

FIG. 11 is a cross-sectional view of the semiconductor device taken along line H-H′ of FIG. 10;

FIG. 12A is a plan view explanatory of a production step of the semiconductor device shown in FIG. 10, in which first to fourth semiconductor chips are stacked on a wiring mother substrate;

FIG. 12B is a cross-sectional view of FIG. 12A;

FIG. 13A is a plan view explanatory of a production step subsequent to FIG. 12A,

FIG. 13B is a cross-sectional view of FIG. 13A;

FIG. 14A is a plan view explanatory of a production step subsequent to FIG. 13A;

FIG. 14B is a cross-sectional view of FIG. 14A;

FIG. 15 is a plan view showing a semiconductor device according to a third embodiment of the present invention, excluding part of a sealing resin;

FIG. 16 is a cross-sectional view of the semiconductor device taken along line L-L′ of FIG. 15;

FIG. 17 is a cross-sectional view showing an example of a semiconductor device to which the present invention is applicable;

FIG. 18 is a plan view showing the semiconductor device shown in FIG. 17 without a sealing resin; and

FIGS. 19A to 19E are cross-sectional views for explaining primary production steps of the semiconductor device shown in FIG. 17 in sequence.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Prior to the explanation of embodiments of the present invention, an example of a semiconductor device to which the present invention is applicable and an outline of a method of manufacturing such a semiconductor device will be described below.

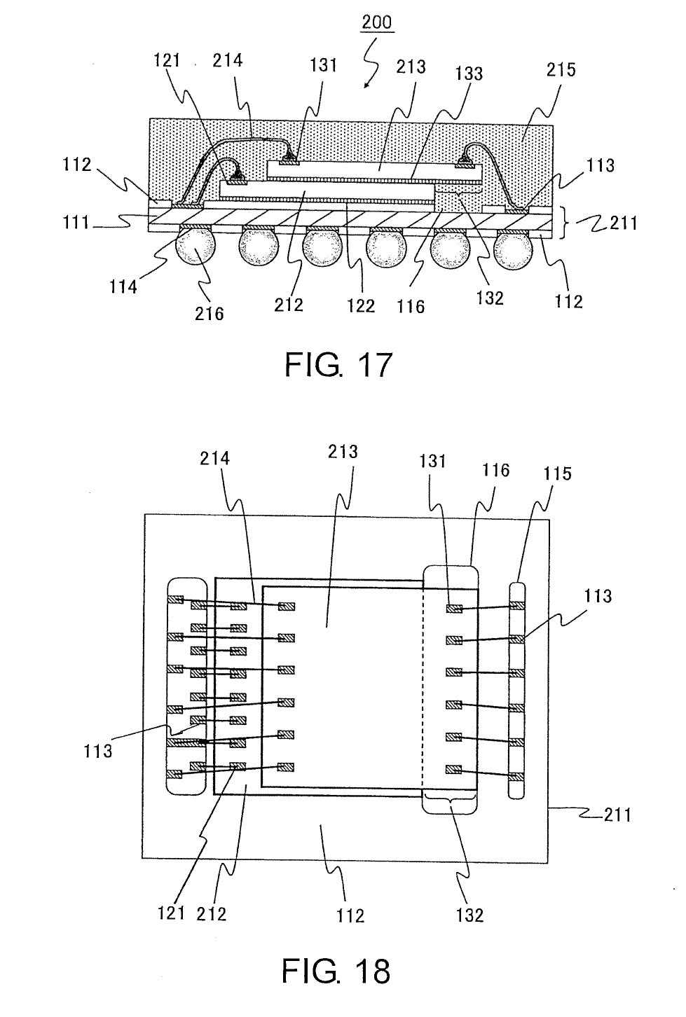

FIGS. 17 and 18 are a cross-sectional view and a plan view showing an outlined structure of a semiconductor device. In the plan view of FIG. 18, a sealing resin or a sealer (215 in FIG. 17) is omitted from the illustration.

The illustrated semiconductor device 200 comprises a wiring substrate 211, a first semiconductor chip 212, a second semiconductor chip 213, wires (bonding wires) 214, a sealing resin 215, and solder balls 216.

For example, the wiring substrate 211 is formed of a glass epoxy substrate that is substantially in the form of a rectangular plate. The wiring substrate 211 includes an insulating substrate 111, wiring layers (not shown) patterned on both sides of the insulating substrate 111, and insulator films (solder resist films) 112 formed so as to cover the wiring layers. A plurality of connection pads 113 are formed on and connected to the wiring layer formed on a first surface of the wiring substrate 211. Furthermore, a plurality of land portions 114 are formed on and connected to the wiring layer formed on a second surface of the wiring substrate 211. As shown in FIG. 18, the connection pads 113 are arranged on the first surface of the wiring substrate 211 near a peripheral portion of the wiring substrate 211. Furthermore, the land portions 114 are arranged in a grid pattern on the second surface of the wiring substrate 211. The connection pads 113 and the land portions 114 are connected to each other by wires connected to the connection pads 113 and the land portions 114, vias extending through the insulating substrate 111, and the like. The wires 214 are connected to the connection pads 113. The solder balls 216 are mounted on the land portions 114.

For example, the insulating films 112 are formed of a solder resist (SR). The insulating films 112 are formed entirely on both surfaces of the wiring substrate 211 except predetermined areas. In other words, part of the insulating films 112 has been removed from the predetermined areas so that the insulating films 112 have one or more opening portions. For example, opening portions 115 and 116 are formed on the first surface of the wiring substrate 211. The opening portions 115 expose an area in which the connection pads 113 are formed and the vicinity thereof. The opening portion 116 exposes an area that faces an overhang portion 132 of the second semiconductor chip 213, which will be described later, or an area broader than the area that faces the overhang portion 132 of the second semiconductor chip 213. Opening portions are also formed in the second surface of the wiring substrate 211 so as to expose the land portions 114.

The first semiconductor chip 212 is substantially in the form of a rectangular plate. Some circuits and electrode pads 121 are formed on a first surface of the first semiconductor chip 212. The electrode pads 121 are arranged along one side of the first semiconductor chip 212. The first semiconductor chip 212 is mounted on the first surface of the wiring substrate 211 near the center of the wiring substrate 211 and located at a position shifted leftward from the center of the wiring substrate 211 in FIG. 18. Specifically, the first semiconductor chip 212 is arranged adjacent to the opening portion 116 so that one side of the first semiconductor chip 212 overlies one side of the opening portion 116. A second surface of the first semiconductor chip 212 is bonded and fixed to a portion of the wiring substrate 211 in which the insulating film 112 of the wiring substrate 211 has been formed by an adhesive member 122 such as a die-attached film (DAF).

The second semiconductor chip 213 is substantially in the form of a rectangular plate as with the first semiconductor chip 212. Some circuits and electrode pads 131 are formed on a first surface of the second semiconductor chip 213. The electrode pads 131 are arranged along a pair of sides of the second semiconductor chip 213.

The second semiconductor chip 213 is stacked and mounted on the first semiconductor chip 212. The second semiconductor chip 213 is located at a position that is shifted rightward from the first semiconductor chip 212 in FIG. 18 so that an area of the first semiconductor chip 212 in which the electrode pads 121 are to be formed is not covered with the second semiconductor chip 213. As a result, part of the second semiconductor chip 213 projects outward from the first semiconductor chip 212 and thus forms an overhang portion 132. In this example, the second semiconductor chip 213 is arranged so as to project in a direction perpendicular to one side of the first semiconductor chip 212. A second surface of the second semiconductor chip 213 is bonded and fixed to the first semiconductor chip 212 by an adhesive member 133 such as a DAF.

For example, the wires 214 are formed of a conductive metal such as Au. The wires 214 electrically connect the electrode pads 121 and 131 and

the corresponding connection pads 113 to each other. The sealing resin 215 is formed of an insulating resin. The first semiconductor chip 212, the second semiconductor chip 213, and the wires 214 are sealed in the sealing resin 215 so that the first surface of the wiring substrate 211 is covered with the sealing resin 215.

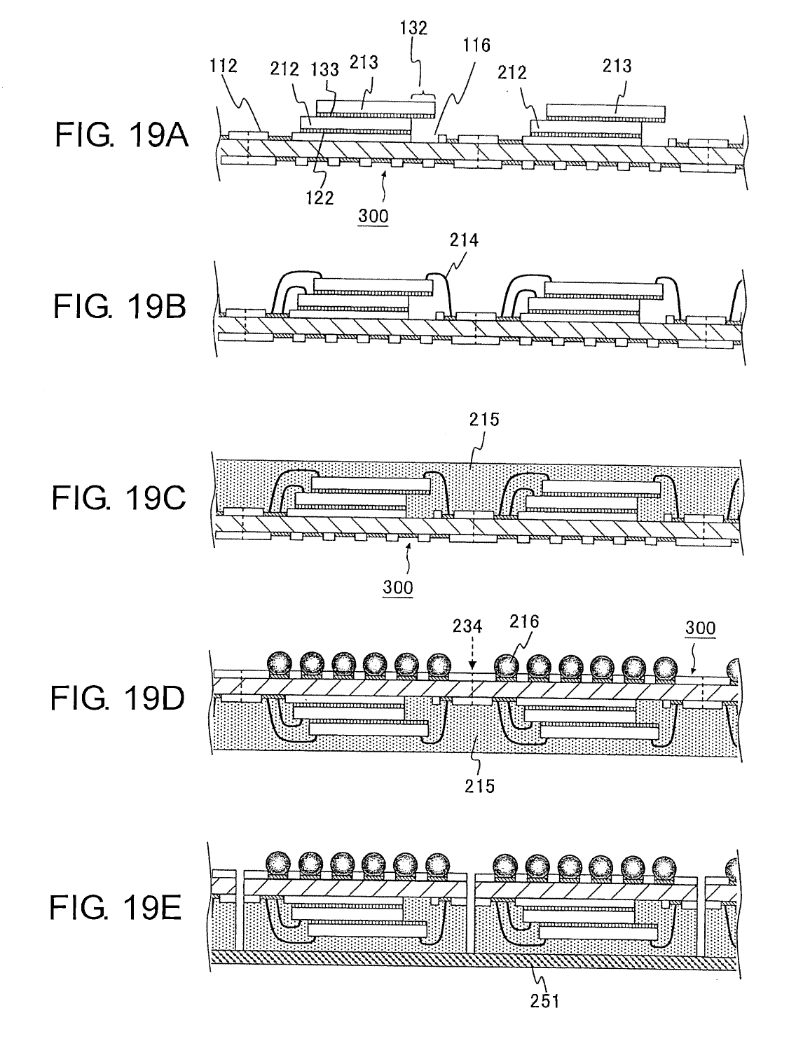

Next, a method of manufacturing a semiconductor device using a wiring mother substrate 300 will be described in sequence with reference to FIGS. 19A to 19E.

First, as shown in FIG. 19A, first semiconductor chips 212 and second semiconductor chips 213 are sequentially mounted on the wiring mother substrate 300. Each of the first semiconductor chips 212 is mounted adjacent to the corresponding opening portion 116 so that one side of the first semiconductor chip 212 overlies one side of the corresponding opening portion 116. The first semiconductor chips 212 are bonded and fixed to the wiring mother substrate 300 by adhesive members 122 such as DAFs provided on lower surfaces of the first semiconductor chips 212. Similarly, the second semiconductor chips 213 are bonded and fixed to upper surfaces of the first semiconductor chips 212 by adhesive members 122 such as DAFs provided on lower surfaces of the second semiconductor chips 213.

The second semiconductor chips 213 are stacked so as to expose the electrode pads 121 (FIG. 17) of the first semiconductor chips 212. Additionally, the second semiconductor chips 213 are arranged such that the overhang portion 132 of each of the second semiconductor chips 213 is located right above at least part of the corresponding opening portion 116. At that time, the overhang portion 132 of each of the second semiconductor chips 213 projects from the first semiconductor chip 12 in a direction perpendicular to a direction of injection of the sealing resin (in the rightward direction in FIG. 19A).

Next, as shown in FIGS. 18 and 19B, the electrode pads 121 of the first semiconductor chips 212 and the corresponding connection pads 113 are connected to each other by wires 214, and the electrode pads 131 of the second semiconductor chips 213 and the corresponding connection pads 113 are connected to each other by wires 214. A wire bonding apparatus (not shown) may be used to connect those wires 214. For example, wire connection is performed by ball bonding that uses an ultrasonic thermo-compression bonding method. Specifically, an end of a wire 214 where a ball has been formed by fusion is bonded to the electrode pad 121 or 131 by an ultrasonic thermo-compression bonding method. Another end of the wire 214 is bonded to the corresponding connection pad 113 by an ultrasonic thermo-compression bonding method so that the wire 214 draws a certain loop shape.

Then, as shown in FIG. 19C, a sealing resin (sealer) 215 is formed on a first surface of the wiring mother substrate 300 by a batch molding process.

Subsequently, as shown in FIG. 19D, a solder ball 216 is mounted onto each of the land portions 114 formed on a second surface of the wiring mother substrate 300. The solder balls 216 are used as external terminals of the semiconductor device 200.

Then, as shown in FIG. 19E, the sealing resin 215 is bonded to a dicing tape 251. Thus, the sealing resin 215 and the wiring mother substrate 300 are supported by the dicing tape 251. Thereafter, the wiring mother substrate 300 and the sealing resin 215 are cut lengthwise and breadthwise along dicing lines 234 (FIG. 19D) with use of a dicing blade (not shown). As a result, the wiring mother substrate 300 is singulated into individual product formation portions. A semiconductor device 200 as shown in FIG. 17 is obtained by picking up one of the singulated product formation portions 33 with the sealing resin 215 from the dicing tape 251.

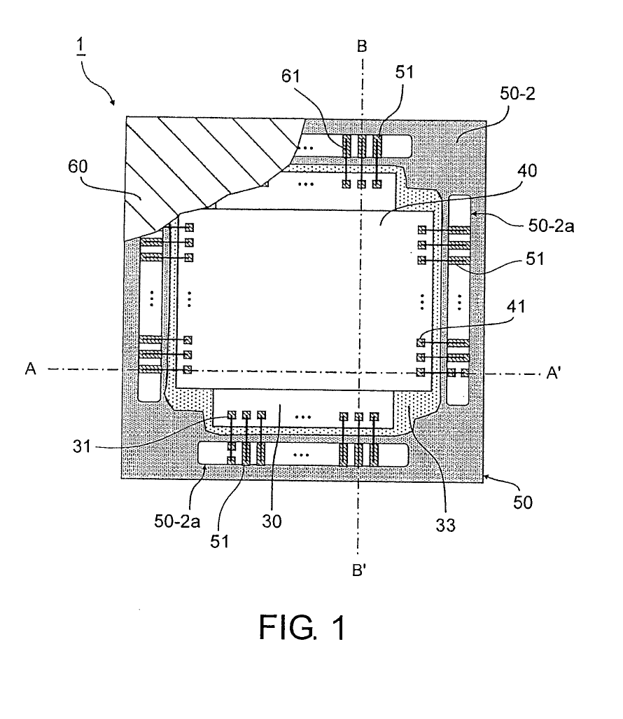

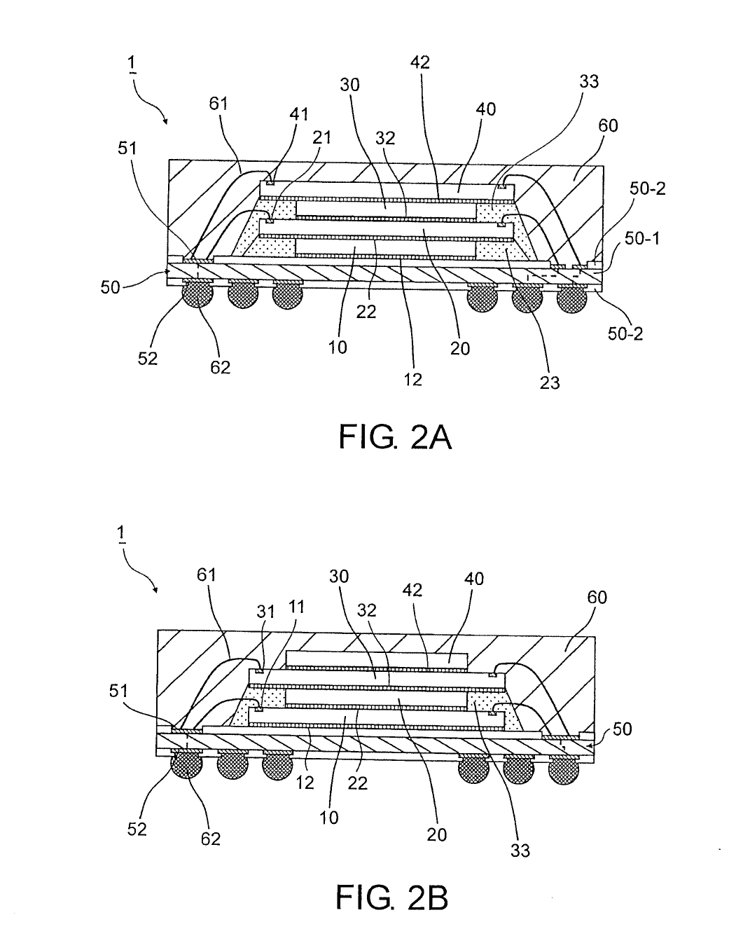

FIG. 1 is a plan view showing a semiconductor device according to a first embodiment of the present invention. FIG. 2A is a cross-sectional view of the semiconductor device taken along line A-A′ of FIG. 1, and FIG. 2B is a cross-sectional view of the semiconductor device taken along line B-B′ of FIG. 1.

In FIGS. 2A and 2B, for example, a wiring substrate 50 is formed of a glass epoxy substrate that is in the form of a rectangular plate. The wiring substrate 50 includes an insulating substrate 50-1, wiring layers (not shown) patterned on both sides of the insulating substrate 50-1, and solder resist films (insulator films) 50-2 formed so as to cover the wiring layers. Four SR opening portions 50-2a are formed along four sides (first, second, third, and fourth edges) of the wiring substrate 50 in the solder resist film 50-2 on a first surface of the wiring substrate 50. A plurality of connection pads 51 are formed on and connected to the exposed wiring layer. Meanwhile, a plurality of land portions 52 are formed on and connected to the wiring layer formed on a second surface of the wiring substrate 50.

In the semiconductor device according to the first embodiment, as shown in FIGS. 1, 2A, and 2B, four semiconductor chips 10, 20, 30, and 40, e.g., memory chips are stacked and mounted on the wiring substrate 50 in numerical order. The four semiconductor chips 10, 20, 30, and 40 have the same circuit configuration and the same pad arrangement. For example, each of the semiconductor chips 10, 20, 30, and 40 is in the form of a rectangular plate. A plurality of electrode pads (first electrodes) 11, 21, 31, and 41 are arranged along short sides (third and fourth sides) of the rectangular shape of each semiconductor chip. Each of the semiconductor chips is stacked on an adjacent semiconductor chip by an adhesive member 12, 22, 32, or 42 such as a die-attached film (DAF) while it is rotated on a plane parallel to its surface through 90 degrees with respect to the adjacent semiconductor chip. Particularly, each of the second-stage semiconductor chip 20 and the fourth-stage semiconductor chip 40 is arranged such that two short side portions of the semiconductor chip overhang or project from the long sides (first and second sides) of an adjacent lower semiconductor chip 10 or 30. Therefore, gaps are formed below the overhang portions of each of the second-stage semiconductor chip 20 and the fourth-stage semiconductor chip 40.

As shown in FIG. 2A, the gaps (first gap) between the short side portions of the second-stage semiconductor chip 20 and the wiring substrate 50 are filled with a first resin layer (lower resin layer), e.g., an underfill material (first underfill 23). The gaps (second gap) between the short side portions of the third-stage semiconductor chip 30 and the first-stage semiconductor chip 10 and the gaps (third gap) between the short side portions of the fourth-stage semiconductor chip 40 and the short side portions of the second-stage semiconductor chip 20 are filled with a second resin layer (upper resin layer), e.g., an underfill material (second underfill 33).

As described above, a plurality of semiconductor chips of a multilayer structure are configured so that the overhang portions of those semiconductor chips are supported by the resin layers being filled. Therefore, a thinner semiconductor chip can be used as a semiconductor chip stacked with overhang portions. Thus, the sealer 60 can be reduced in thickness, and hence the semiconductor device 1 can be reduced in thickness. Furthermore, reduction in thickness of the sealer 60 results in reduction of warp of the semiconductor device 1. Since a resin is filled as an underfill for overhang portions of a semiconductor chip, voids are prevented from being generated in the overhang portions. Therefore, the reliability of the semiconductor device can be improved.

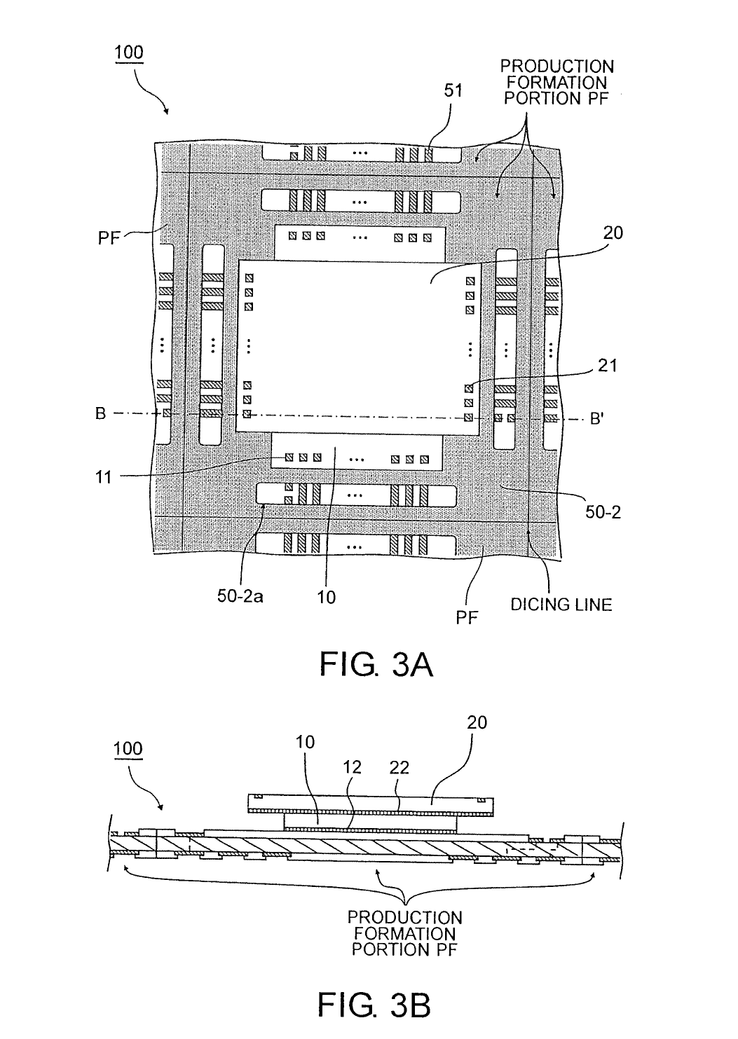

FIGS. 3A to 9A are plan views showing an assembly flow (production steps) of a semiconductor device according to the first embodiment of the present invention. FIGS. 3B to 9B are cross-sectional views thereof. The production steps of a semiconductor device of the first embodiment are basically the same as the production steps of a semiconductor device described in connection with FIGS. 19A to 19E. Primary differences exist in filling steps of the first and second underfills 23 and 33.

As shown in FIGS. 3A and 3B, a wiring mother substrate 100 having a plurality of product formation portions PF arranged in the form of a matrix is prepared. FIGS. 3A and 3B show one product formation portion and part of four product formation portions surrounding it.

A first semiconductor chip 10 is mounted substantially at a central position of each of the product formation portions on the wiring mother substrate 100 via an adhesive member 12 such as a DAF. Subsequently, a second semiconductor chip 20 is mounted on the first semiconductor chip 10 in a state in which it is rotated on a plane parallel to its surface through 90 degrees with respect to the first semiconductor chip 10. Specifically, the short sides of the second semiconductor chip 20 are perpendicular to the short sides of the first semiconductor chip 10. Furthermore, the second semiconductor chip 20 is stacked on the first semiconductor chip 10 so that portions near the short sides of the second semiconductor chip 20 (short side portions) overhang from the long sides of the first semiconductor chip 10. In FIGS. 3A and 3B, both of the portions near the short sides of the second semiconductor chip 20 overhang from both of the long sides of the first semiconductor chip 10. Thus, gaps are formed between the short side portions of the second semiconductor chip 20 and the wiring mother substrate 100. The short side portions may be called projecting parts.

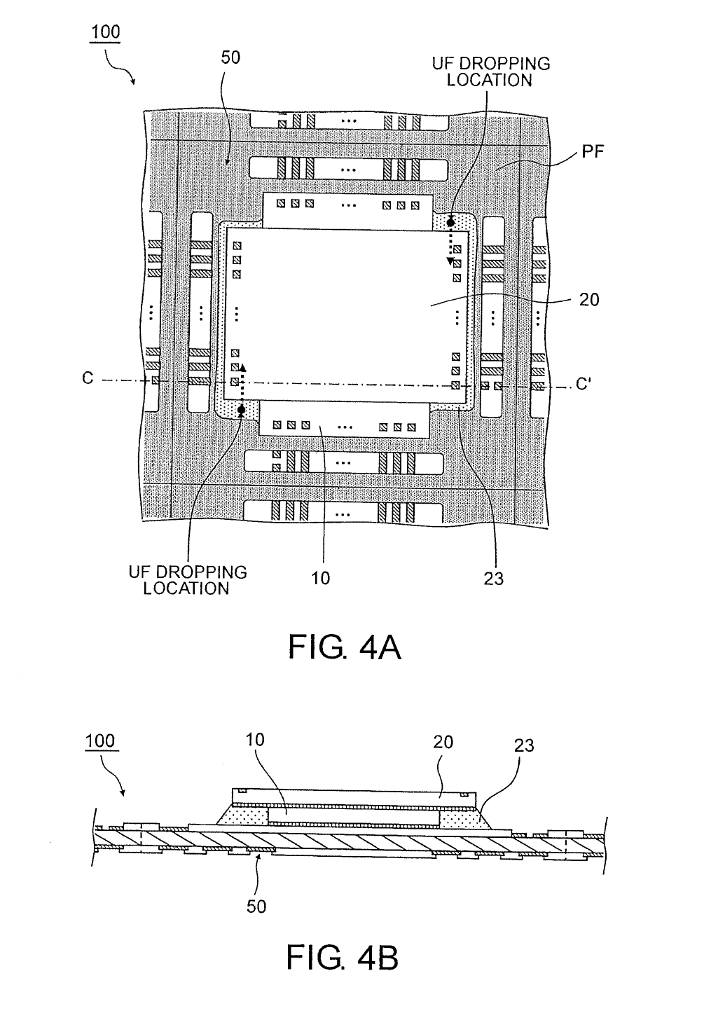

Then, as shown in FIGS. 4A and 4B, a first underfill 23 (first resin layer) is supplied from locations near the long sides of the second semiconductor chip 20 along directions parallel to the short sides of the second semiconductor chip 20 so that the gaps formed below the overhang portions of the second semiconductor chip 20 are filled with the first underfill 23. As indicated by the UF dropping locations in FIG. 4A, the underfill is dropped at locations near a pair of diagonal corners of the second semiconductor chip 20 and supplied to the gaps formed below the overhang portions. The underfill material dropped near the wiring substrate 50 flows from the long sides of the second semiconductor chip 20 to the gaps formed below the overhang portions of the second semiconductor chip 20 because of the capillary phenomenon. Thus, those gaps are filled with the underfill material. After the filling of the underfill material, the wiring mother substrate 100 is baked at a predetermined temperature, e.g., about 140° C., to harden the underfill material. In this manner, the overhang portions of the second semiconductor chip 20 are supported by the first resin (first underfill 23). Accordingly, a thinner semiconductor chip can be used as the second semiconductor chip 20, which overhangs from the first semiconductor chip 10. (The resin spreads more widely near the dropping locations.) Since the underfill is dropped near the long sides of the second semiconductor chip 20, a risk of covering the electrode pads arranged near the short sides of the first semiconductor chip 10 with the underfill can be lowered even if the underfill spreads on the first semiconductor chip 10.

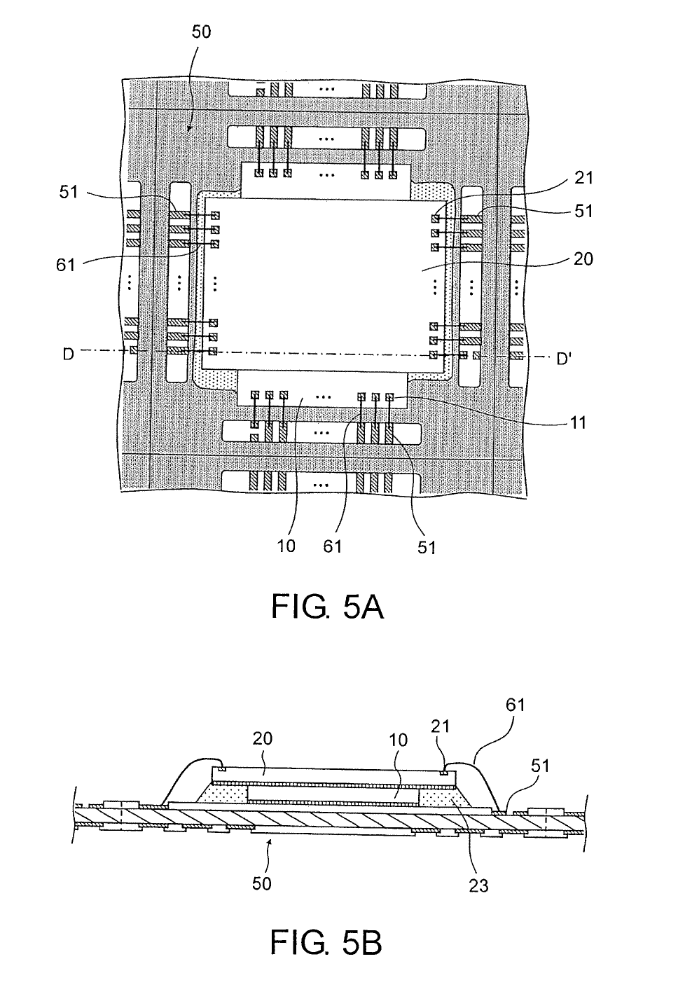

Next, a wire bonding process is performed as shown in FIGS. 5A and 5B. Specifically, the electrode pads (first electrodes) 11 of the first semiconductor chip 10 and the connection pads (first connection pads) 51 of the wiring substrate 50 are electrically connected to each other by conductive wires (first wires) 61, and the electrode pads (second electrodes) 21 of the second semiconductor chip 20 and the connection pads (first connection pads) 51 of the wiring substrate 50 are electrically connected to each other by conductive wires (second wires) 61. For example, those wires are formed of Au. Since the gaps formed below the overhang portions of the second semiconductor chip 20 have been filled with the first underfill 23 (first resin layer) so that the overhang portions of the second semiconductor chip 20 are supported by the first underfill 23, the electrode pads 21 arranged in the overhang portions of the second semiconductor chip 20 can be connected by wires without chip cracks or warp even if the second semiconductor chip 20 is thin.

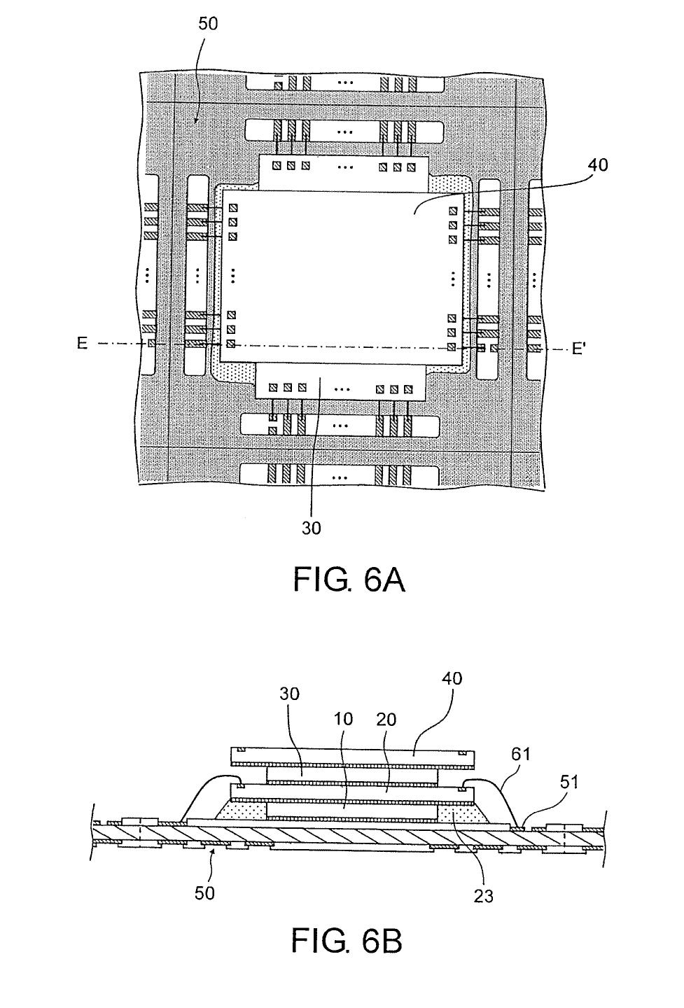

As shown in FIGS. 6A and 6B, a third semiconductor chip 30 and a fourth semiconductor chip 40 are stacked on the second semiconductor chip 20. Specifically, as with the second semiconductor chip 20, the third semiconductor chip 30 is stacked on the second semiconductor chip 20 in a state in which it is rotated on a plane parallel to its surface through 90 degrees with respect to the second semiconductor chip 20. The third semiconductor chip 30 is arranged such that portions near the short sides (seventh and eighth sides) of the third semiconductor chip 30 (short side portions) overhang from the long sides of the second semiconductor chip 20. In FIGS. 6A and 6B, the third semiconductor chip 30 is located at the same two-dimensional position as the first semiconductor chip 10. Similarly, the fourth semiconductor chip 40 is stacked on the third semiconductor chip 30 in a state in which it is rotated on a plane parallel to its surface through 90 degrees with respect to the third semiconductor chip 30. The fourth semiconductor chip 40 is arranged such that portions near the short sides (seventh and eighth sides) of the fourth semiconductor chip 40 (short side portions) overhang from the long sides (fifth and sixth sides) of the third semiconductor chip 30. The fourth semiconductor chip 40 is located at the same two-dimensional position as the second semiconductor chip 20.

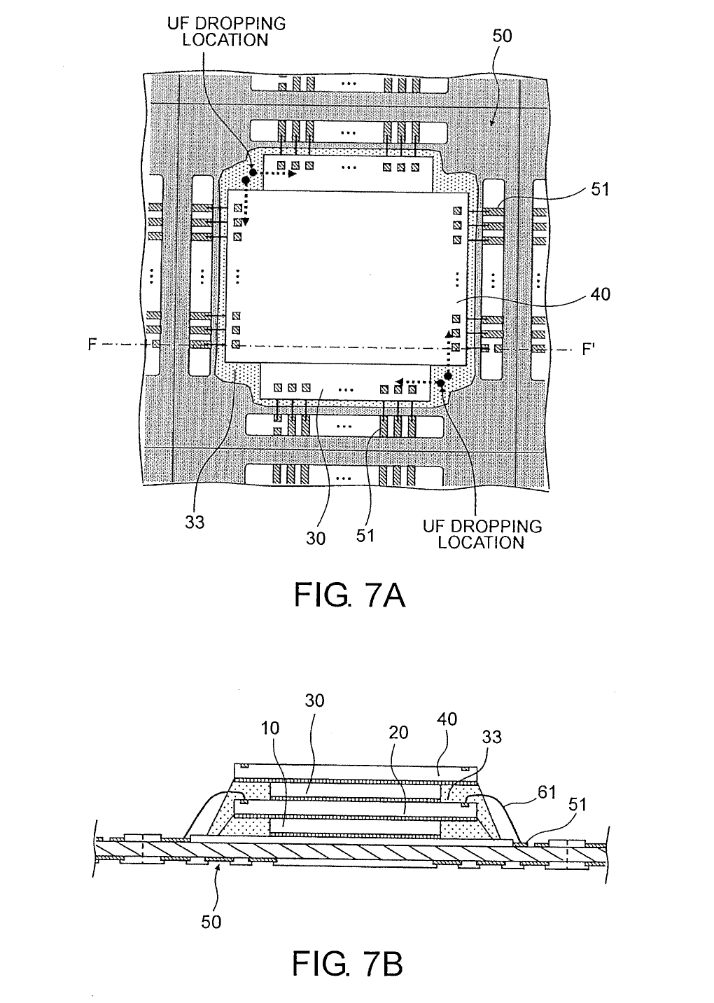

Then, as shown in FIGS. 7A and 7B, a second underfill 33 (second resin layer) is supplied from locations that are different from the dropping locations of the first underfill 23 (first resin layer) so that the gaps formed between the short side portions of the third semiconductor chip 30 and the short side portions of the first semiconductor chip 10 and the gaps formed between the short side portions of the fourth semiconductor chip 40 and the short side portions of the second semiconductor chip 20 are filled with the second underfill 33. The second underfill 33 is dropped at locations that are different from the dropping locations of the first underfill 23. In this example, the second underfill 33 is dropped at locations near another pair of diagonal corners of the second semiconductor chip 20. This configuration suppresses expansion of the underfill on the wiring substrate 50, so that both of the gaps formed below the overhang portions of the third semiconductor chip 30 and the gaps formed below the overhang portions of the fourth semiconductor chip 40 can simultaneously be filled with the underfill. After the filling of the underfill material, the wiring mother substrate 100 is baked at a predetermined temperature, e.g., about 140° C., to harden the second underfill material. In this manner, the overhang portions of the third semiconductor chip 30 and the overhang portions of the fourth semiconductor chip 40 are supported by the second underfill 33 (second resin layer). Accordingly, thinner semiconductor chips can be used as the third semiconductor chip 30, which overhangs from the second semiconductor chip 20, and the fourth semiconductor chip 40, which overhangs from the third semiconductor chip 30. Additionally, part of the wires 61 connected to the electrode pads 11 of the first semiconductor chip 10, which are located below the overhang portions of the third semiconductor chip 30, is covered with the second underfill 33 filled below the overhang portions of the third semiconductor chip 30. Part of the wires 61 connected to the electrode pads 21 of the second semiconductor chip 20, which are located below the overhang portions of the fourth semiconductor chip 40, is covered with the second underfill 33 filled below the overhang portions of the fourth semiconductor chip 40. Advantages to be brought by such configurations will be described later.

The second underfill 33 is dropped at locations that are different from the dropping locations of the first underfill 23 so that expansion of the underfill material is suppressed on the wiring substrate 50. Thus, a risk of the underfill material spreading over the connection pads 51 on the wiring substrate 50 can be lowered. Furthermore, expansion of the underfill material is suppressed in the gaps formed between the second, third, and fourth semiconductor chips, so that those gaps can readily be filled with the underfill material.

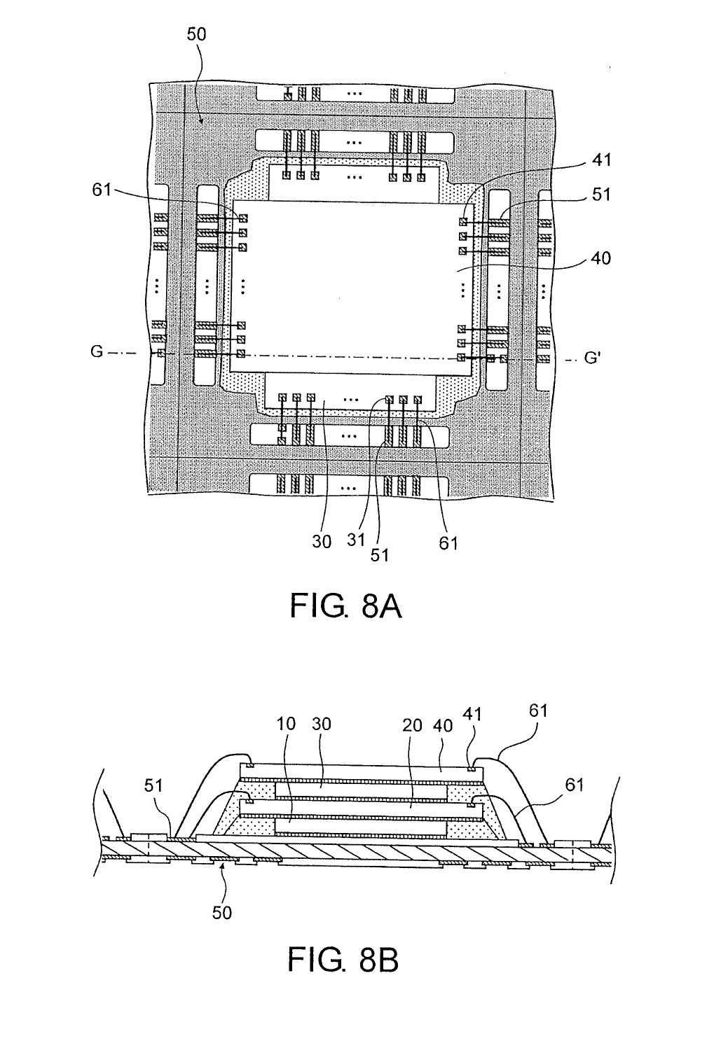

Next, a wire bonding process is performed as shown in FIGS. 8A and 8B. Specifically, the electrode pads (third electrodes) 31 of the third semiconductor chip 30 and the connection pads (second connection pads) 51 of the wiring substrate 50 are electrically connected to each other by conductive wires (third wires) 61, and the electrode pads (fourth electrodes) 41 of the fourth semiconductor chip 40 and the connection pads (second connection pads) 51 of the wiring substrate 50 are electrically connected to each other by conductive wires (fourth wires) 61. Since the gaps formed below the overhang portions of the third semiconductor chip 30 and the gaps formed below the overhang portions of the fourth semiconductor chip 40 have been filled with the second underfill 33 (second resin layer) so that the overhang portions of the third semiconductor chip 30 and the overhang portions of the fourth semiconductor chip 40 are supported by the second underfill 33, the electrode pads arranged in the overhang portions of the third semiconductor chip 30 and the fourth semiconductor chip 40 can be connected by wires without chip cracks or warp even if the third semiconductor chip 30 and the fourth semiconductor chip 40 are thin. Common pins of the electrode pads 31 and 41 of the third and fourth semiconductor chips 30 and 40 are connected to the connection pads connected to the electrode pads 11 and 21 of the first and second semiconductor chips 10 and 20 by the wires. Independent pins of the electrode pads 31 and 41 of the third and fourth semiconductor chips 30 and 40 are connected to the connection pads that are electrically independent of the electrode pads 11 and 21 of the first and second semiconductor chips 10 and 20 by the wires.

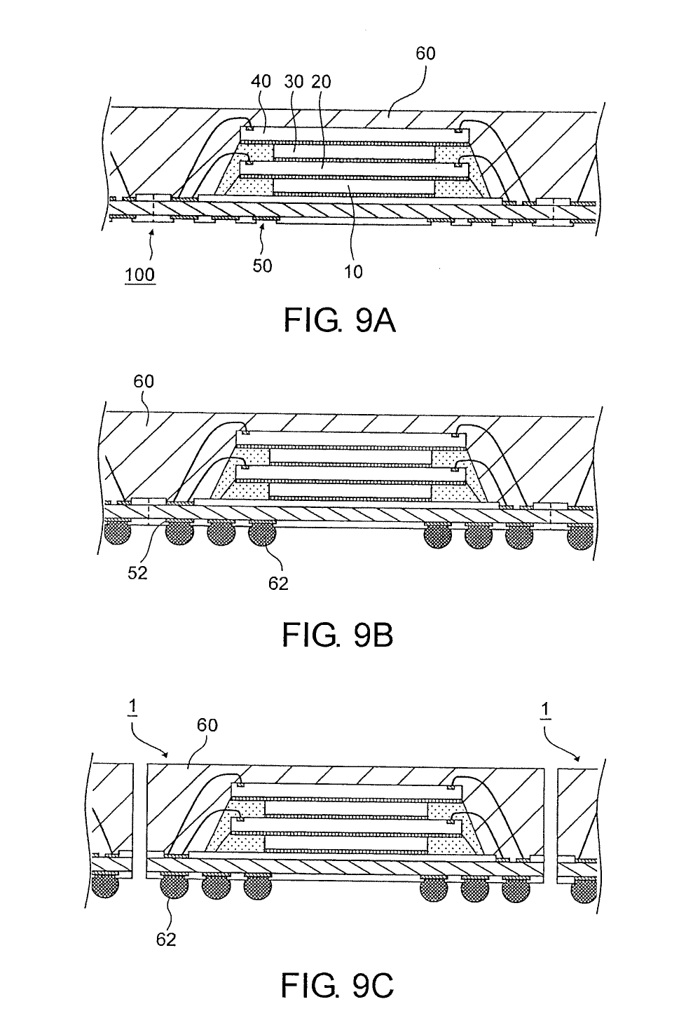

Then, as shown in FIG. 9A, a sealer (sealing resin) 60 is formed on the first surface of the wiring mother substrate 100 by a batch molding process of resin so that a plurality of product formation portions PF are collectively covered with the sealer.

Subsequently, as shown in FIG. 9B, a solder ball 62 is mounted onto each of the land portions 52 formed on the second surface of the wiring mother substrate 100. The solder balls 216 are used as external terminals of the semiconductor device 1.

FIG. 9B illustrates the mounting step of the solder balls in a vertically inversed manner. For example, solder balls 62 may be mounted by using a suction mechanism (not shown) having a plurality of suction holes arranged so as to correspond to the land portions 52. In this case, a plurality of solder balls are attracted to the suction mechanism. Flux is transferred to and formed on the solder balls being held. Thus, the solder balls are collectively mounted onto the land portions 52 of the wiring mother substrate 100. Thereafter, the solder balls 62 and the land portions 52 are connected and fixed to each other by reflow processing.

Then, as described in connection with FIG. 19E, the sealer 60 is bonded to a dicing tape so that the sealer 60 and the wiring mother substrate 100 are supported by the dicing tape. Thereafter, the wiring mother substrate 100 and the sealer 60 are cut lengthwise and breadthwise along dicing lines with use of a dicing blade (not shown). As a result, the wiring mother substrate 100 is singulated into individual product formation portions as illustrated in FIG. 9C. A semiconductor device 1 as shown in FIG. 1 is obtained by picking up one of the singulated product formation portions with the sealer 60 from the dicing tape.

In the first embodiment, the gaps formed below the overhang portions of the second, third, and fourth semiconductor chips 20, 30, and 40 are filled with the underfill material. Therefore, voids are prevented from being generated below those overhang portions during molding. Thus, the sealer 60 can satisfactorily be formed. Furthermore, since those overhang portions are supported by the underfill materials (resin layers) formed below the overhang portions, thin semiconductor chips can be stacked and mounted even though the overhang portions are provided in the semiconductor chips. Accordingly, the thickness of resin of the sealer 60 can be reduced. Thus, the semiconductor device can be reduced in thickness. Moreover, in the first embodiment, part of the wires 61 connected to the electrode pads 11 of the first semiconductor chip 10, which are located below the overhang portions of the third semiconductor chip 30, and part of the wires 61 connected to the electrode pads 21 of the second semiconductor chip 20, which are located below the overhang portions of the fourth semiconductor chip 40, are covered with the underfill material (second underfill 33). Therefore, those wires are prevented from being carried away by the flow of the resin during a batch molding process. Short circuits of the wires are also prevented. Thus, the reliability of the semiconductor device can be improved.

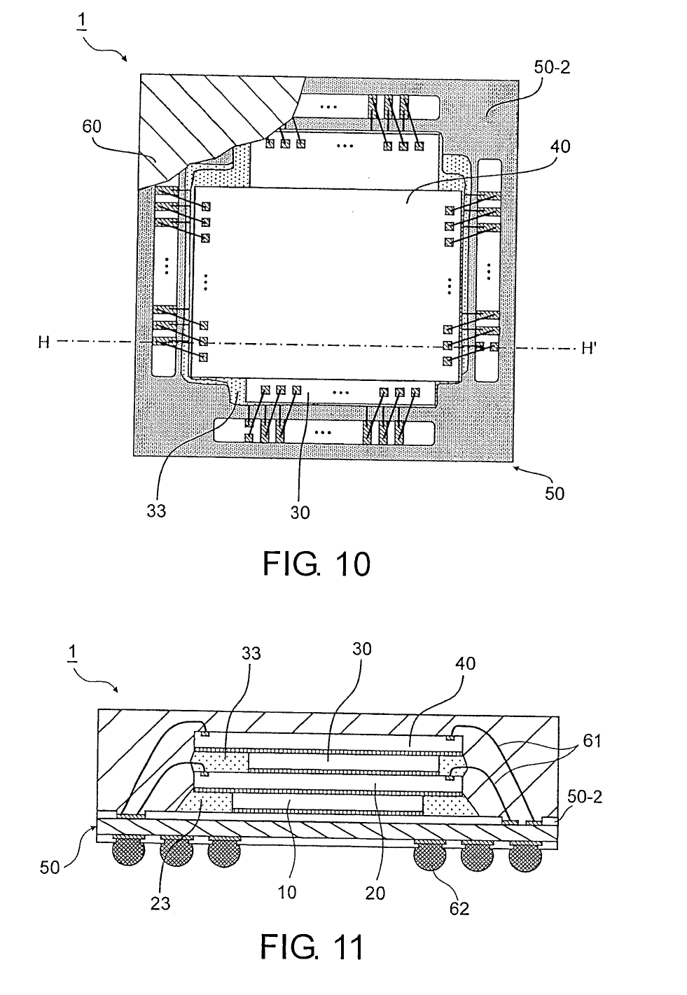

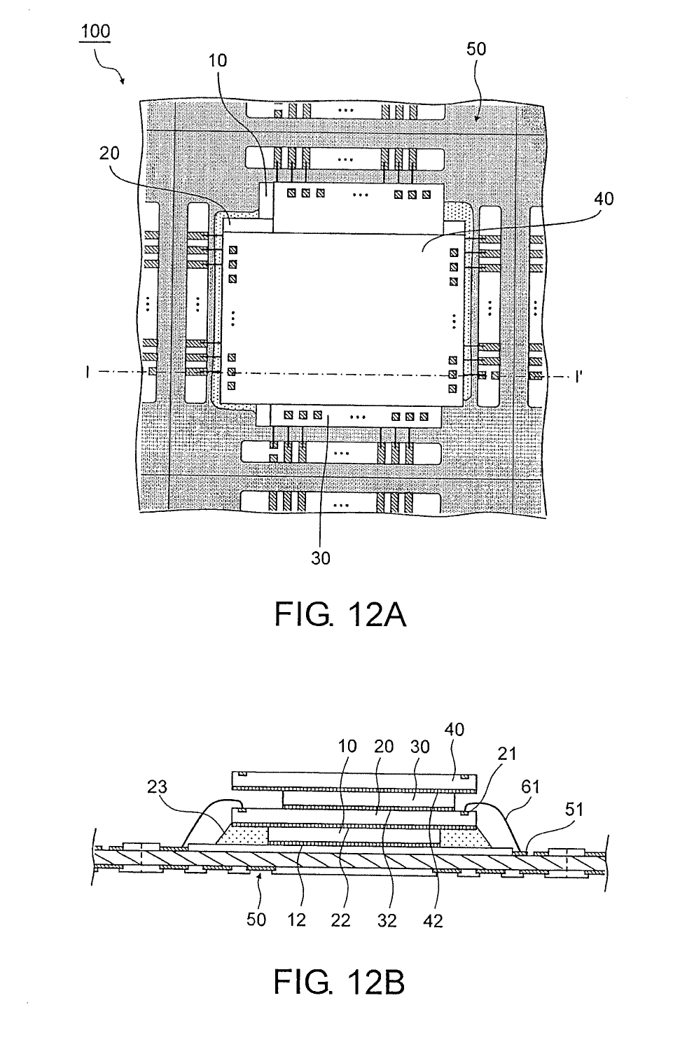

FIG. 10 is a plan view showing a semiconductor device according to a second embodiment of the present invention, excluding part of a sealing resin. FIG. 11 is a cross-sectional view of the semiconductor device taken along line H-H′ of FIG. 10. FIGS. 12A to 14A are plan views showing an assembly flow (production steps) of the semiconductor device shown in FIG. 10. FIGS. 12B to 14B are cross-sectional views thereof.

The semiconductor device according to the second embodiment is configured in the same manner as the semiconductor device according to the first embodiment except for the following points. The second embodiment differs from the first embodiment in that the third semiconductor chip 30 located at a third stage and the fourth semiconductor chip 40 located at a fourth stage are two-dimensionally shifted from the first semiconductor chip 10 and the second semiconductor chip 20, respectively.

Referring to FIGS. 12A and 12B, a first semiconductor chip 10 is mounted substantially at a central position of each of the product formation portions on the wiring mother substrate 100 via an adhesive member 12 such as a DAF, as with the first embodiment. Subsequently, a second semiconductor chip 20 is mounted on the first semiconductor chip 10 in a state in which it is rotated on a plane parallel to its surface through 90 degrees with respect to the first semiconductor chip 10. Both of portions near the short sides of the second semiconductor chip 20 (short side portions) overhang from both of the long sides of the first semiconductor chip 10. Thus, gaps are formed between the short side portions of the second semiconductor chip 20 and the wiring mother substrate 100. Then, a first underfill 23 (first resin layer) is supplied from locations near the long sides of the second semiconductor chip 20 along directions parallel to the short sides of the second semiconductor chip 20 so that the gaps formed below the overhang portions of the second semiconductor chip 20 are filled with the first underfill 23. The underfill material dropped near the wiring substrate 50 flows from the long sides of the second semiconductor chip 20 to the gaps formed below the overhang portions of the second semiconductor chip 20 because of the capillary phenomenon. Thus, those gaps are filled with the underfill material. After the filling of the underfill material, the wiring mother substrate 100 is baked at a predetermined temperature, e.g., about 140° C., to harden the underfill material. Next, a wire bonding process is performed so that the electrode pads 11 of the first semiconductor chip 10 and the electrode pads 21 of the second semiconductor chip 20 are electrically connected to the connection pads 51 of the wiring substrate 50, respectively, by conductive wires (bonding wires) 61, for example, Au wires.

Thereafter, a third semiconductor chip 30 and a fourth semiconductor chip 40 are stacked on the second semiconductor chip 20. Specifically, as with the second semiconductor chip 20, the third semiconductor chip 30 is stacked on the second semiconductor chip 20 in a state in which it is rotated on a plane parallel to its surface through 90 degrees with respect to the second semiconductor chip 20. The third semiconductor chip 30 is arranged such that portions near the short sides of the third semiconductor chip 30 (short side portions) overhang from the long sides of the second semiconductor chip 20. At that time, the third semiconductor chip 30 is displaced in a direction perpendicular to the long sides thereof. As a result, the third semiconductor chip 30 is shifted rightward in FIG. 12A with respect to the first semiconductor chip 10. Similarly, the fourth semiconductor chip 40 is stacked on the third semiconductor chip 30 in a state in which it is rotated on a plane parallel to its surface through 90 degrees with respect to the third semiconductor chip 30. The fourth semiconductor chip 40 is arranged such that portions near the short sides of the fourth semiconductor chip 40 overhang from the long sides of the third semiconductor chip 30. At that time, the fourth semiconductor chip 40 is displaced in a direction perpendicular to the long sides thereof. As a result, the fourth semiconductor chip 40 is shifted downward in FIG. 12A with respect to the second semiconductor chip 20. For example, the amount of shift may be about 0.3 mm.

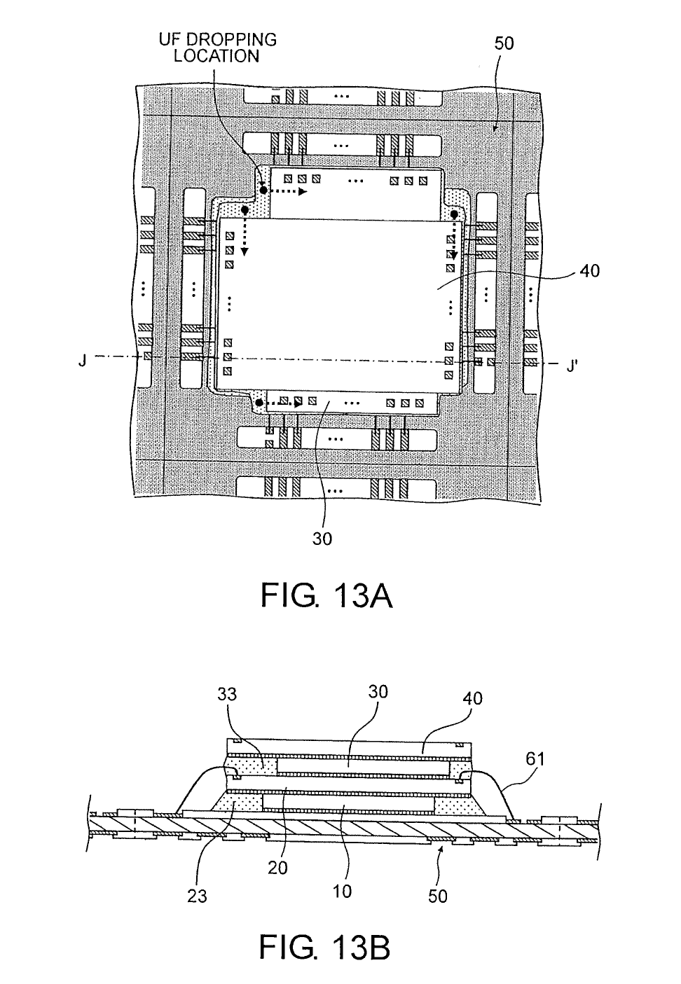

Referring to FIGS. 13A and 13B, the third and fourth semiconductor chips 30 and 40 are arranged at positions shifted in different directions with 90 degrees. An underfill material is dropped onto the first and second semiconductor chips 10 and 20 from two-dimensional areas having no overlaps of the chips, one of which is indicated as the UF dropping location in FIG. 13A. As a result, the gaps formed between the short side portions of the third semiconductor chip 30 and the short side portions of the first semiconductor chip 10 and the gaps formed between the short side portions of the fourth semiconductor chip 40 and the short side portions of the second semiconductor chip 20 are filled with the second underfill 33 (second resin layer).

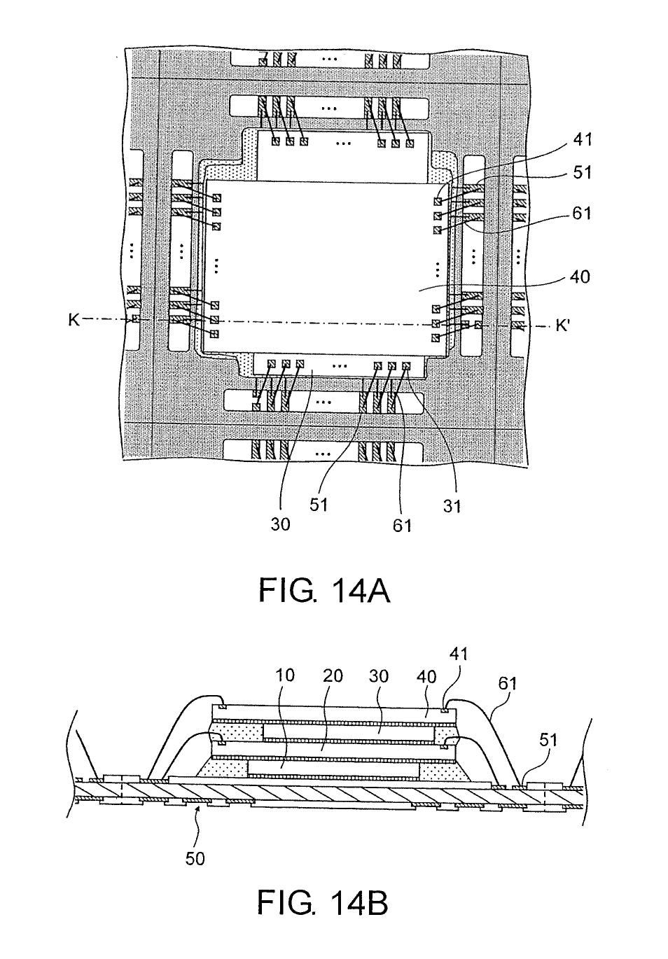

Then a wire bonding process as shown in FIGS. 14A and 14B is performed so that the electrode pads 31 of the third semiconductor chip 30 and the electrode pads 41 of the fourth semiconductor chip 40 are electrically connected to the connection pads 51 of the wiring substrate 50, respectively, by conductive wires 61, for example, Au wires. Since the gaps formed below the overhang portions of the third semiconductor chip 30 and the gaps formed below the overhang portions of the fourth semiconductor chip 40 have been filled with the second underfill 33 (second resin layer) so that the overhang portions of the third semiconductor chip 30 and the fourth semiconductor chip 40 are supported by the second underfill 33, the electrode pads arranged in the overhang portions of the third semiconductor chip 30 and the fourth semiconductor chip 40 can be connected by wires without chip cracks or warp even if the third semiconductor chip 30 and the fourth semiconductor chip 40 are thin. Subsequently, a sealing process is performed. This sealing process is the same as the sealing process described in connection with FIGS. 9A to 9C. Therefore, detailed explanation of this sealing process is omitted herein.

Thus, the semiconductor device according to the second embodiment exhibits the same advantageous effects as the semiconductor device according to the first embodiment. Furthermore, the third semiconductor chip 30 and the fourth semiconductor chip 40 are arranged at two-dimensional positions shifted from the first semiconductor chip 10 and the second semiconductor chip 20, respectively, so that an underfill material can be dropped onto the first and second semiconductor chips 10 and 20. Therefore, expansion of the underfill can further be suppressed on the wiring substrate.

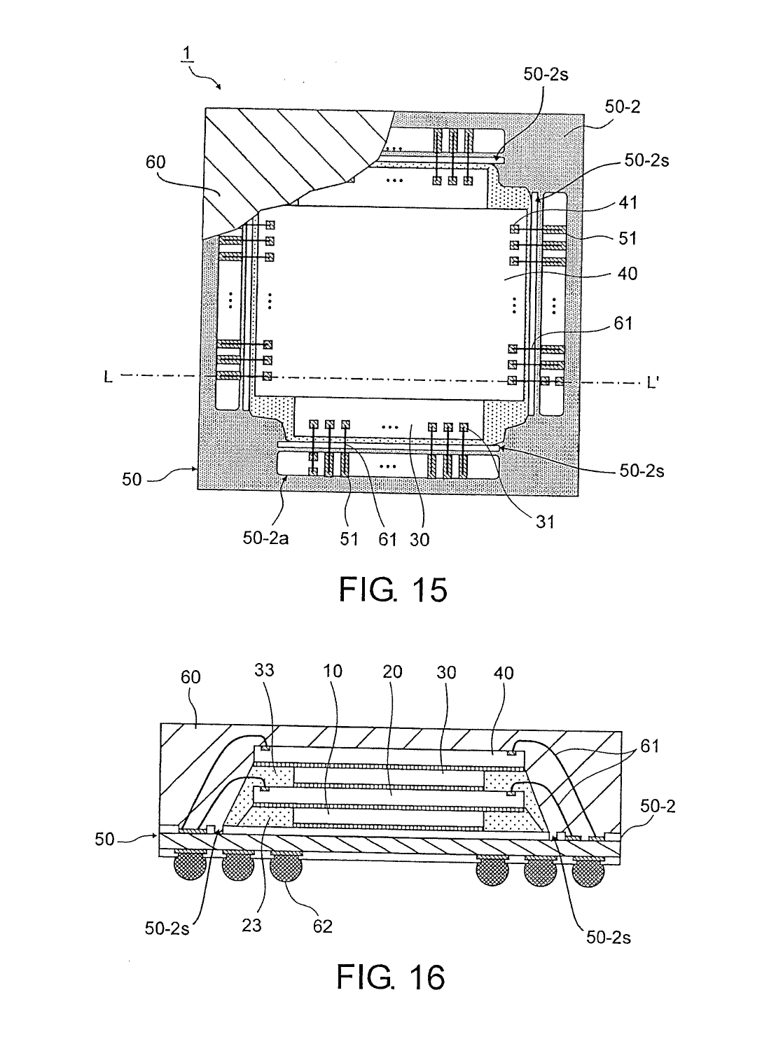

FIG. 15 is a plan view showing a semiconductor device according to a third embodiment of the present invention, excluding part of a sealing resin. FIG. 16 is a cross-sectional view of the semiconductor device taken along line L-L′ of FIG. 15.

The semiconductor device according to the third embodiment is configured in the same manner as the semiconductor device according to the first embodiment except for the following points. The third embodiment differs from the first embodiment in that slits 50-2s are formed in a solder resist film (insulating layer) 50-2 of the wiring substrate 50 between SR opening portions 50-2a for forming the connection pads 51 in the wiring substrate 50 and an area in which semiconductor chips are mounted. As shown in FIG. 15, four slits 50-2s are arranged along four sides of a roughly rectangular mounting area in which semiconductor chips are mounted, so that those slits 50-2s surround the mounting area. Projections (protrusions) may be formed instead of those slits.

The semiconductor device according to the third embodiment exhibits the same advantageous effects as the semiconductor device according to the first embodiment. Additionally, the semiconductor device according to the third embodiment exhibits the following advantageous effects: Since the slits 50-2s are formed in the solder resist film 50-2 formed on a surface of the wiring substrate 50 between the SR opening portions 50-2a and the mounting area of the semiconductor chips, the slits 50-2s serve as dams (weirs) for the underfill material. Therefore, expansion of the underfill material on the wiring substrate 50 can be suppressed. Thus, a risk of covering the connection pads 51 with the underfill can be lowered. As a matter of course, the third embodiment may be applied to the second embodiment.

Although the present invention has been described based upon some embodiments, the present invention is not limited to the aforementioned embodiments. It should be understood that many modifications and variations may be made therein without departing from the spirit and scope of the present invention.

In the above embodiments, the semiconductor device has a cross stacking structure of four semiconductor chips having the same pad arrangement. Nevertheless, the present invention is applicable to any semiconductor device as long as semiconductor chips are stacked with multiple stages so as to have overhang portions.

Furthermore, four semiconductor chips are mounted on the wiring substrate in the above embodiments. Nevertheless, the present invention may be applied to an MCP having two or three stages of semiconductor chips being mounted, or an MCP having five or more stages of semiconductor chips being mounted.

Moreover, in the above embodiments, the wiring substrate is formed of a glass epoxy substrate. Nevertheless, the wiring substrate may be a flexible wiring substrate formed of a polyimide substrate.

Some or all of the above embodiments can be described as in the following notes. Nevertheless, the present invention is not limited to those notes.

### (Note 1)

A semiconductor device comprising:

a wiring substrate having a plurality of connection pads;

a first semiconductor chip mounted on the wiring substrate, the first semiconductor chip having a roughly rectangular shape;

a second semiconductor chip stacked on the first semiconductor chip so that part of the first semiconductor chip is exposed, the second semiconductor chip having a roughly rectangular shape;

a third semiconductor chip stacked on the second semiconductor chip so that part of the third semiconductor chip projects from the second semiconductor chip so as to form gaps between the projecting part of the third semiconductor chip and part of the first semiconductor chip, the third semiconductor chip having a roughly rectangular shape; and

an upper resin filled between the part of the first semiconductor chip and the projecting part of the third semiconductor chip.

### (Note 2)

The semiconductor device as recited in Note 1, wherein the second semiconductor chip is stacked on the first semiconductor chip so that part of the second semiconductor chip projects from the first semiconductor chip so as to form gaps between the projecting part of the second semiconductor chip and the wiring substrate, and

the semiconductor device further comprises a lower resin filled between the projecting part of the second semiconductor chip and the wiring substrate.

### (Note 3)

The semiconductor device as recited in Note 2, further comprising:

a fourth semiconductor chip stacked on the third semiconductor chip so that part of the fourth semiconductor chip projects from the third semiconductor chip so as to form gaps between the projecting part of the fourth semiconductor chip and part of the second semiconductor chip, the fourth semiconductor chip having a roughly rectangular shape, the upper resin being filled between the projecting part of the fourth semiconductor chip and the part of the second semiconductor chip; and

a sealing resin formed on the wiring substrate so that the first, second, third, and fourth semiconductor chips, the upper resin, and the lower resin are covered with the sealing resin.

### (Note 4)

The semiconductor device as recited in Note 3, wherein the parts of the first, second, third, and fourth semiconductor chips are located on short sides of those semiconductor chips,

the first, second, third, and fourth semiconductor chips respectively have first, second, third, and fourth electrodes along the short sides thereof,

the first, second, third, and fourth electrodes are connected to corresponding ones of the connection pads by first, second, third, and fourth wires, respectively,

part of the first wires connected to the first electrodes of the first semiconductor chip that are located below the short side portions of the third semiconductor chip is covered with the upper resin filled in the gaps between the first semiconductor chip and the third semiconductor chip, and

part of the second wires connected to the second electrodes of the second semiconductor chip is covered with the upper resin filled in the gaps between the second semiconductor chip and the fourth semiconductor chip.

### (Note 5)

The semiconductor device as recited in Note 3 or 4, wherein the third semiconductor chip is stacked on the second semiconductor chip in a state in which the third semiconductor chip is shifted in a direction perpendicular to long sides of the third semiconductor chip, and

the fourth semiconductor chip is stacked on the third semiconductor chip in a state in which the fourth semiconductor chip is shifted in a direction perpendicular to long sides of the fourth semiconductor chip.

### (Note 6)

The semiconductor device as recited in any one of Notes 1 to 5, wherein a rectangular mounting area in which semiconductor chips are to be mounted is predetermined in the wiring substrate,

the connection pads are formed along each of four edges of the mounting area, and

a plurality of slits or protrusions are formed in the wiring substrate between each of the four edges of the mounting area and the connection pads arranged along each of the four edges of the mounting area.

What is claimed is:

1. A method of manufacturing a semiconductor device, the method comprising:
preparing a wiring substrate having a plurality of connection pads;
mounting a first rectangular semiconductor chip having a plurality of first electrodes arranged along short sides thereof on the wiring substrate;
stacking a second rectangular semiconductor chip having a plurality of second electrodes arranged along short sides thereof on the first semiconductor chip so that the short sides of the second semiconductor chip are perpendicular to the short sides of the first semiconductor chip and that gaps are formed between the wiring substrate and short side portions of the second semiconductor chip;
filling the gaps with a first resin from locations near long sides of the second semiconductor chip in a direction parallel to the short sides of the second semiconductor chip;
electrically connecting the first electrodes and the connection pads to each other by first wires; and
electrically connecting the second electrodes and the connection pads to each other by second wires after the filling of the first resin.

2. The method as recited in claim 1, further comprising:
stacking a third rectangular semiconductor chip having a plurality of third electrodes arranged along short sides thereof on the second semiconductor chip so that the short sides of the third semiconductor chip are perpendicular to the short sides of the second semiconductor chip and that gaps are formed between short side portions of the first semiconductor chip and short side portions of the third semiconductor chip;
stacking a fourth rectangular semiconductor chip having a plurality of fourth electrodes arranged along short sides thereof on the third semiconductor chip so that the short sides of the fourth semiconductor chip are perpendicular to the short sides of the third semiconductor chip and that gaps are formed between the short side portions of the second semiconductor chip and short side portions of the fourth semiconductor chip;
filling the gaps between the first semiconductor chip and the third semiconductor chip and the gaps between the second semiconductor chip and the fourth semiconductor chip with a second resin;
electrically connecting the third electrodes and the connection pads to each other by third wires; and
electrically connecting the fourth electrodes and the connection pads to each other by fourth wires.

3. The method as recited in claim 1, wherein the gaps are filled with the first resin from locations near a first pair of diagonal corners of the second semiconductor chip.

4. The method as recited in claim 2, wherein the gaps are filled with the second resin from locations near a second pair of diagonal corners of the second semiconductor chip.

5. The method as recited in claim 4, wherein both of the gaps between the first semiconductor chip and the third semiconductor chip and the gaps between the second semiconductor chip and the fourth semiconductor chip are simultaneously filled with the second resin.

6. The method as recited in claim 4, wherein part of the first wires connected to the first electrodes of the first semiconductor chip that are located below the short side portions of the third semiconductor chip is covered with the second resin filled in the gaps between the first semiconductor chip and the third semiconductor chip, and
part of the second wires connected to the second electrodes of the second semiconductor chip is covered with the second resin filled in the gaps between the second semiconductor chip and the fourth semiconductor chip.

7. The method as recited in claim 2, wherein the stacking of the third semiconductor chip includes stacking the third semiconductor chip on the second semiconductor chip in a state in which the third semiconductor chip is shifted in a direction perpendicular to long sides of the third semiconductor chip, and
the stacking of the fourth semiconductor chip includes stacking the fourth semiconductor chip on the third semiconductor chip in a state in which the fourth semiconductor chip is shifted in a direction perpendicular to long sides of the fourth semiconductor chip.

8. The method as recited in claim 2, further comprising:
predetermining, in the wiring substrate, a rectangular mounting area in which semiconductor chips are to be mounted;
forming the connection pads along each of four edges of the mounting area; and
forming a plurality of slits or protrusions in the wiring substrate between each of the four edges of the mounting area and the connection pads arranged along each of the four edges of the mounting area for suppressing expansion of the first resin and the second resin.

9. A method of manufacturing a semiconductor device, the method comprising:
preparing a wiring substrate including a plurality of connection pads;
mounting a first semiconductor chip over the wiring substrate;
stacking a second semiconductor chip over the first semiconductor chip so that at least one side of the second semiconductor chip protrudes from the first semiconductor chip to form a first gap between the wiring substrate and the second semiconductor chip, the second semiconductor chip including a plurality of first electrodes arranged along the one side thereof; and
filling the first gap with a first resin, after stacking the second semiconductor chip over the first semiconductor chip.

10. The method as recited in claim 9, further comprising:
electrically connecting the first electrodes to the connection pads by first wires, after filling the first gap with the first resin.

11. The method as recited in claim 10, further comprising:
stacking a third semiconductor chip over the second semiconductor chip so that at least one side of the third semiconductor chip protrudes from the second semiconductor chip to form a second gap between the first semiconductor chip and the third semiconductor chip, the third semiconductor chip including a plurality of second electrodes arranged along the one side thereof;
filing the second gap with a second resin;
electrically connecting the second electrodes to the connection pads by second wires, after filling the second gap with the second resin.

12. The method as recited in claim 11, further comprising:
before filling the second gaps with the second resin, stacking a fourth semiconductor chip over the third semiconductor chip so that at least one side of the fourth semiconductor chip protrudes from the third semiconductor chip to form a third gap between the second semiconductor chip and the fourth semiconductor chip, the fourth semiconductor chip including a plurality of third electrodes arranged along the one side thereof,
wherein both of the second gap and third gap are simultaneously filled with the second resin.

13. A method of manufacturing a semiconductor device, the method comprising:
preparing a wiring substrate including a first surface that is defined by first and second edges opposite to each other and by third and fourth edges opposite to each other, the wiring substrate including a plurality of first connection pads arranged along each of the first and second edges thereof;
preparing first and second semiconductor chips, each of the first and second semiconductor chips is defined by first and second sides opposite to each other and by third and fourth sides opposite to each other, the first and second sides being longer than the third and fourth sides, each of the first and second semiconductor chips including a plurality of first electrodes arranged along each of the third and fourth sides thereof;
mounting the first semiconductor chip over the first surface of the wiring substrate so that the first and second sides of the first semiconductor chip face toward the first and second edges of the wiring substrate;
stacking the second semiconductor chip over the first semiconductor chip so that the first and second sides of the second semiconductor chip face toward the third and fourth edges of the wiring substrate, the third and fourth sides of the second semiconductor chip being protruded from the first and second sides of the first semiconductor chip toward the first and second edges of the wiring substrate to form first gaps between the wiring substrate and the second semiconductor chip;
filling the first gaps with a first resin, after stacking the second semiconductor chip over the first semiconductor chip; and
electrically connecting the first electrodes of the second semiconductor chip to the first connection pads by first wires, after filling the first gaps with the first resin.

14. The method as recited in claim 13, wherein the wiring substrate includes a plurality of second connection pads arranged along each of the third and fourth edges thereof, and the method further comprising:
electrically connecting the first electrodes of the first semiconductor chip to the second connection pads by second wires.

15. The method as recited in claim 13, further comprising:
preparing third and fourth semiconductor chips, each of the third and fourth semiconductor chips is defined by fifth and sixth sides opposite to each other and by seventh and eighth sides opposite to each other, the fifth and sixth sides being longer than the seventh and eighth sides, each of the third and fourth semiconductor chips including a plurality of second electrodes arranged along each of the seventh and eighth sides thereof;
stacking the third semiconductor chip over the second semiconductor chip so that the fifth and sixth sides of the third semiconductor chip face toward the first and second edges of the wiring substrate, the seventh and eighth sides of the third semiconductor chip being protruded from the first and second sides of the second semiconductor chip toward the third and fourth edge of the wiring substrate to form second gaps between the first semiconductor chip and the third semiconductor chip;
stacking the fourth semiconductor chip over the third semiconductor chip so that the fifth and sixth sides of the fourth semiconductor chip face toward the third and fourth edges of the wiring substrate, the seventh and eighth sides of the fourth semiconductor chip being protruded from the fifth and sixth sides of the third semiconductor chip toward the first and second edges of the wiring substrate to form third gaps between the second semiconductor chip and the fourth semiconductor chip;
filling the second gaps between the first semiconductor chip and the third semiconductor chip and the third gaps between the second semiconductor chip and fourth semiconductor chip with a second resin;
electrically connecting the second electrodes of the third semiconductor chip to the second connection pads by third wires, after filling the second gaps and the third gaps with the second resin; and
electrically connecting the second electrodes of the fourth semiconductor chip to the first connection pads by fourth wires, after filling the second gaps and the third gaps with the second resin.

16. The method as recited in claim 13, wherein the first gaps are filled with the first resin from locations near a first pair of diagonal corners of the second semiconductor chip.

17. The method as recited in claim 15, wherein both of the second gaps and the third gaps are simultaneously filled with the second resin.

18. The method as recited in claim 15, wherein part of the first wires connected to the first electrodes of the second semiconductor chip is covered with the second resin filled in the third gaps between the second semiconductor chip and the fourth semiconductor chip.

19. The method as recited in claim 15, wherein the third semiconductor chip is stacked over the second semiconductor chip so that the fifth and sixth sides of the third semiconductor chip overlap to the first and second sides of the first semiconductor chip, and
the fourth semiconductor chip is stacked over the third semiconductor chip so that the fifth and sixth sides of the fourth semiconductor chip overlap to the first and second sides of the second semiconductor chip.

20. The method as recited in claim 15, wherein the third semiconductor chip is stacked over the second semiconductor chip so that the third semiconductor chip deviates from the first semiconductor chip in a direction that is perpendicular to the first side of the first semiconductor chip, and
the fourth semiconductor chip is stacked over the third semiconductor chip so that the fourth semiconductor chip deviates from the second semiconductor chip in a direction that is perpendicular to the first side of the second semiconductor chip.
